(19) United States
(12) Patent Application Publication
(10) Pub. No.: US 2014/0015579 A1
(43) Pub. Date: Jan. 16, 2014

(54) SYSTEM HAVING HALF-CYCLE PRECISION

(71) Applicants: David Shkolnik, Haifa (IL); Igal Sadoun, Ashdod (IL)

(72) Inventors: David Shkolnik, Haifa (IL); Igal Sadoun, Ashdod (IL)

(73) Assignee: DSPG GROUP LTD., Herzliya (IL)

(21) Appl. No.: 13/549,557

(22) Filed: Jul. 16, 2012

(51) Int. Cl. H03L 7/00

(52) U.S. Cl. 327/160

(57) ABSTRACT

A system that may include a slow clock event generator arranged to generate the slow clock event; a fast clock edge type detector that is arranged to perform a determination process of determining whether an earliest fast clock edge that occurs within a slow clock event is a rising clock edge or a falling clock edge, and whether a last fast clock edge that occurs within the slow clock event is a rising clock edge or a falling clock edge; and a counter module that is arranged to count fast clock cycles during the slow clock event to provide a duration estimate indicative of duration of the slow clock event and generate a slow clock event duration value indicative of the duration of the slow clock event, in response to the duration estimate and to a determination result that is indicative of an outcome of the determination process.

### BACKGROUND OF THE INVENTION

Various electronic circuits may utilize clock signals of different frequencies. Typically, a fast clock is used to measure the duration of an event within a slow clock domain.

When the slow clock and the fast clock are not mutually synchronized the measurement exhibits an uncertainty of two fast clock cycles. This uncertainty may result from different possible time gaps between changes in the slow clock and the fast clock.

There is a growing need to provide an efficient device for counting clock cycles with half-cycle precision that will reduce the total uncertainty to one cycle.

### SUMMARY OF THE INVENTION

These may be provided a system for measuring a slow clock event, the system may include a slow clock event generator arranged to generate the slow clock event; a fast clock edge type detector, coupled to the slow clock event generator, that is arranged to perform a determination process that comprises determining whether an earliest fast clock edge that occurs within the slow clock event is a rising clock edge or a falling clock edge, and whether a last fast clock edge that occurs within the slow clock event is a rising clock edge or a falling clock edge; and a counter module that is arranged to: count fast clock cycles during the slow clock event to provide a duration estimate indicative of a duration of the slow clock event; and generate a slow clock event duration value indicative of the duration of the slow clock event, in response to the duration estimate and in response to a determination result that is indicative of an outcome of the determination process.

The counter module may include a half cycle adjustment module that may be arranged to determine whether to amend the duration estimate by one half of a fast clock cycle; and a full cycle counter that may be arranged to provide the duration estimate.

The half cycle adjustment module may be arranged to determine whether to (a) add one half of a fast clock cycle to the duration estimate, (b) reduce one half of the fast clock cycle from the duration estimate, or (c) remain the duration estimate unchanged.

The half cycle adjustment module may be arranged to determine to add one half of the fast clock cycle to the duration estimate if the determination result indicates that the earliest fast clock edge and the last fast clock cycles are falling clock edges.

The half cycle adjustment module may be arranged to determine to reduce one half of the fast clock cycle from the duration estimate if the determination result indicates that the earliest fast clock edge and the last fast clock cycles are raising clock edges.

The half cycle adjustment module may be arranged to determine to leave the duration estimate unchanged if the determination result indicates that one of the earliest fast clock edge and the last fast clock edge is a falling clock edge and another clock edge of the earliest fast clock edge and the last fast clock edge is a raising clock edge.

The half cycle adjustment module may be arranged to select only between an addition of one half of a fast clock cycle to the duration estimate or not to add one half of a fast clock cycle to the duration estimate.

The full cycle counter may include a fast clock counter that may be arranged to start counting fast clock cycles one fast clock cycle after a start of the slow clock event, to provide an initial duration estimate.

The half cycle adjustment module may be arranged to select to add one half of the fast clock cycle to the duration estimate if the determination result indicates that the earliest fast clock edge and the last fast clock edge are both falling clock edges or raising clock edges.

The half cycle adjustment module may be arranged to select to add one half of the fast clock cycle to the duration estimate if the determination result indicates that one of the earliest fast clock edge and the last fast clock edge is a falling clock edge and another clock edge of the earliest fast clock edge and the last fast clock edge is a raising clock edge.

The full cycle counter may include a fast clock counter that may be arranged to start counting fast clock cycles one fast clock cycle after a start of the slow clock event, to provide an initial duration estimate.

The full cycle counter is further adapted to generate a duration estimate that equals the initial duration estimate if the determination result indicates that one of the earliest fast clock edge and the last fast clock edge is a falling clock edge and another clock edge of the earliest fast clock edge and the last fast clock edge is a raising clock edge

The fast clock edge type detector may include a fast clock rising edge synchronizer arranged to provide a rising edge enable signal indicative of first period that starts at an occurrence of an earliest rising edge of the fast clock during the slow clock event and ends at a first rising edge of the fast clock after an end of the slow clock event; and a fast clock falling edge synchronizer arranged to provide a falling edge enable signal indicative of first period that starts at an occurrence of an earliest falling edge of the fast clock during the slow clock event and ends at a first falling edge of the fast clock after an end of the slow clock event.

The fast clock edge type detector may include a comparator that may be arranged to compare timing of changes in values of the rising edge enable signal with timing of changes in values of the falling edge enable signal to determine to provide the determination result.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof may best be understood by reference to the following detailed description when read with the accompanying drawings in which:

FIG. 1 illustrates a system according to an embodiment of the invention;

FIGS. 2-5 illustrate various modules of the system according to an embodiment of the invention; and

FIGS. 6-7 illustrate various modules of the system according to an embodiment of the invention; and

FIG. 8 illustrates a method according to an embodiment of the invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE DRAWINGS

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

Because the illustrated embodiments of the present invention may for the most part, be implemented using electronic components and modules known to those skilled in the art, details will not be explained in any greater extent than that considered necessary as illustrated above, for the understanding and appreciation of the underlying concepts of the present invention and in order not to obfuscate or distract from the teachings of the present invention.

The term “clock” usually refers to a clock signal.

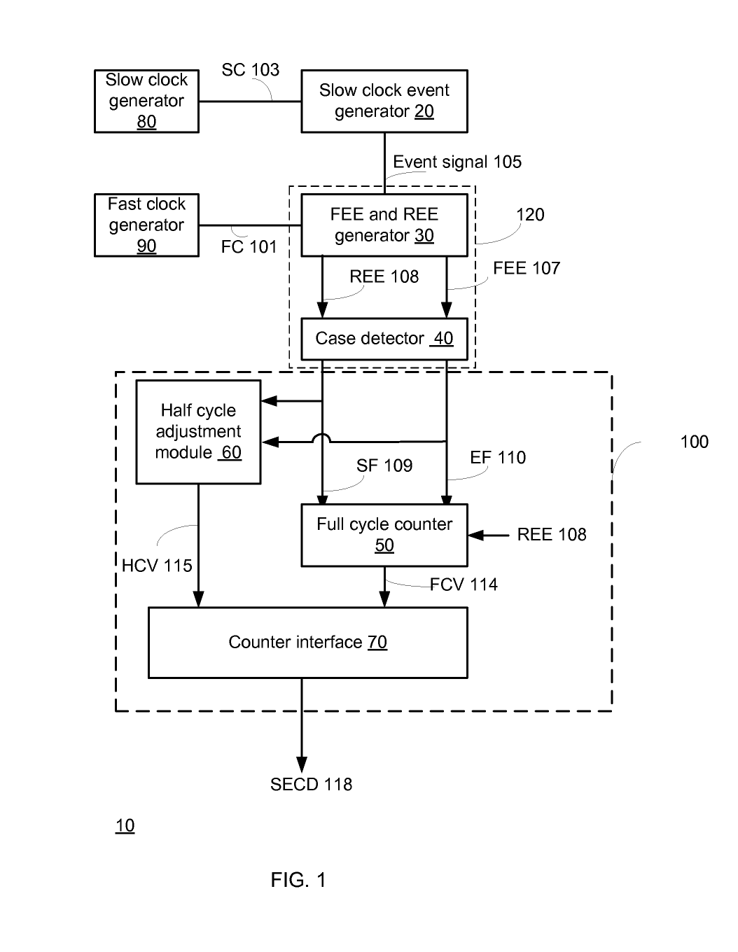

FIG. 1 illustrates a system 10 for measuring a slow clock event, according to an embodiment of the invention.

System 10 may include a slow clock generator 80, a fast clock generator 90, a slow clock event generator 20, a fast clock edge type detector 120, and a counter module 100.

The slow clock generator 80 is arranged to provide a slow clock (SC) 103 to the slow clock event generator 20. The slow clock event generator 20 is arranged to generate a slow clock event that will be measured by other components of the system.

The slow clock event can be, for example, an assertion of an event signal 105 during a time window—the duration of which is being measured by the system 10.

The event signal 105 may be provided to a fast clock edge type detector 120 that is arranged to perform a determination process that may include (a) determining whether an earliest fast clock edge that occurs within the slow clock event is a rising clock edge or a falling clock edge, and (b) determining whether a last fast clock edge that occurs within the slow clock event is a rising clock edge or a falling clock edge.

The fast clock edge type detector 120 can output multiple signals that form a determination result.

The counter module 100 is arranged to count fast clock cycles during the slow clock event to provide a duration estimate indicative of the duration of the slow clock event. The counter module 100 may generate and output a slow clock event duration value (SCED) 118 indicative of the duration of the slow clock event, in response to (a) the duration estimate and in response to (b) a determination result that is indicative of an outcome of the determination process.

FIG. 1 illustrates the counter module 100 as including (a) A half cycle adjustment module 60 that is arranged to determine whether to amend the duration estimate by one half of a fast clock cycle, and (b) a full cycle counter 50 that is arranged to provide the duration estimate.

The half cycle adjustment module 60 can output a half clock cycle value (HCV) 115 and the full cycle counter 50 can output a duration estimate such as a full clock value (FCV) 114.

The a half cycle adjustment module 60 and the full cycle counter 50 may be coupled to a counter interface 70 that can output the slow clock event duration value 118.

The counter interface 70 may add or subtract the HCV 115 from the FCV 114. If, for example, the HCV 115 is either zero or one half of a fast clock cycle and it can be only added to FCV 114 then the HCV 115 can be regarded as the least significant bit of the slow clock event duration value 118 and the counter interface 70 can merely output both signals HCV 115 and FCV 114.

### Zero, Positive and Negative Valued HCV

According to an embodiment of the invention the half cycle adjustment module 60 is arranged to determine whether to (a) add one half of a fast clock cycle to the duration estimate (also referred to as COUNT), (b) reduce one half of the fast clock cycle from the duration estimate, or (c) leave the duration estimate unchanged.

In this case the counter interface 70 may be arranged to subtract or add one half of a fast clock cycle from the duration estimate. Accordingly, HCV 115 can be either one of (a) +0.5 fast clock cycle, (b) −0.5 fast clock cycle, and (c) 0.

According to an embodiment of the invention the half cycle adjustment module 60 is arranged to determine to add one half of the fast clock cycle to the duration estimate if the determination result (provided by the fast clock edge type detector 120) indicates that the earliest fast clock edge and the last fast clock cycles are falling clock edges.

According to an embodiment of the invention the half cycle adjustment module 60 is arranged to determine to add or subtract one half of the fast clock cycle to the duration estimate if the determination result (provided by the fast clock edge type detector 120) indicates that the earliest fast clock edge and the last fast clock cycles are raising clock edges.

According to an embodiment of the invention the half cycle adjustment module 60 is arranged to determine to leave the duration estimate unchanged if the determination result (provided by the fast clock edge type detector 120) indicates that one of the earliest fast clock edge and the last fast clock edge is a falling clock edge and another clock edge of the earliest fast clock edge and the last fast clock edge is a raising clock edge.

Table 1 illustrates the relationship between the type of the clock edges associated with the start and the end of the slow clock event and the values of HCV 115, FCV 114 and the SCED 118.

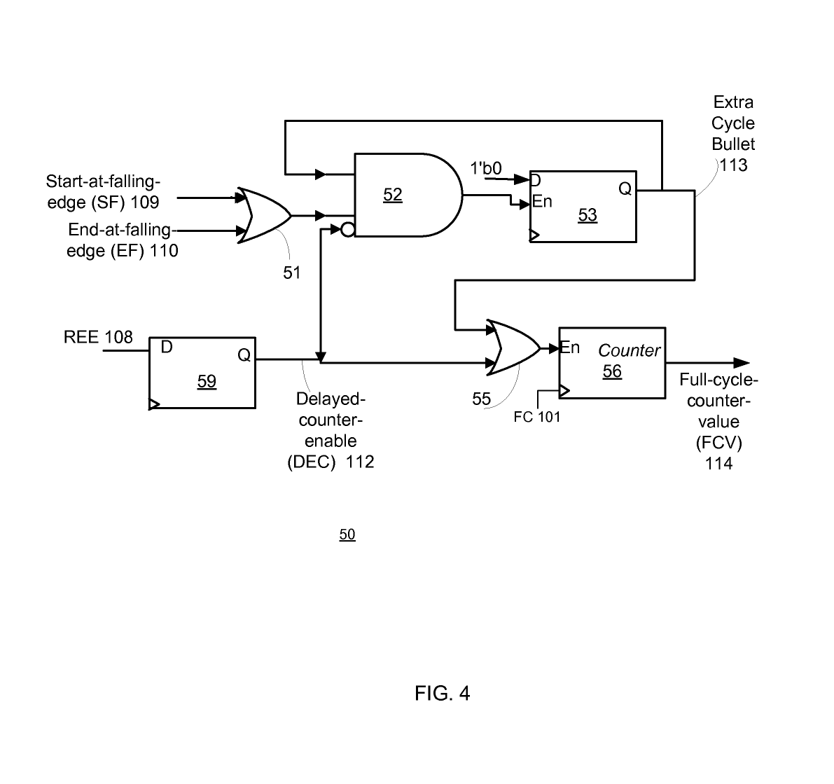

Variable COUNT indicates the number of fast clock cycles counted by a fast clock counter (denoted 56 in FIG. 4) of the full cycle counter 50 during the slow clock event, the fast clock counter starts counting at the earliest positive edge of the fast clock that occurs during the slow clock event.

TABLE 1

| Earliest | | | | |
|---|---|---|---|---|
| clock | | | | |
| edge | Last clock edge | HCV 115 | FCV 114 | SCED 118 |
| Rising edge | Rising edge | −0.5 | COUNT | COUNT − 0.5 |
| Falling edge | Falling edge | +0.5 | COUNT | COUNT + 0.5 |
| Rising edge | Falling edge | 0 | COUNT | COUNT |
| Falling edge | Rising edge | 0 | COUNT | COUNT |

### Positive and Zero Valued HCV

According to an embodiment of the invention the half cycle adjustment module 60 module is arranged to select only between an addition of one half of a fast clock cycle to the duration estimate or not to add one half of a fast clock cycle to the duration estimate.

According to an embodiment of the invention these zero of half cycle values of the HCV 115 can be added to the FCV 114 but the full cycle counter 50 may be required to adjust its FCV 114 according to the type of edges.

According to an embodiment of the invention the full cycle counter 50 can generate an initial duration estimate 119 and determine, based upon the type of fast clock edges associated with the earliest and the last fast clock cycles, whether to provide the initial duration estimate as FCV 114 or to add one fast clock cycle to the initial duration estimate 119 to provide FCV 114.

Referring to table 1, the initial duration estimate (IDE) 119 can have a value of COUNT-1 that equals one fast clock cycle less than a number of fast clock cycles that should have been counted by a fast clock counter (denoted 56 in FIG. 4) of the full cycle counter 50 during the slow clock event, if the fast clock counter started counting at the earliest positive edge of the fast clock that occurs during the slow clock event.

COUNT-1 can be obtained in various manners. According to an embodiment of the invention COUNT-1 is obtained by causing the fast clock counter 56 to start counting at the second positive edge of the fast clock and not at the earliest positive edge during the slow clock event.

FIG. 4 illustrates a flip-flop 58 that delays the beginning of the counting process of the fast clock counter 56 by one fast clock cycle. Alternatively, the fast clock counter 56 can be arranged to start counting from an initial value of minus one.

Table 2 illustrates the relationship between the type of the clock edges associated with the start and the end of the slow clock event and the values of HCV 115, IDE 119, FCV 114 and the SCED 118.

The full cycle counter 50 outputs FCV 114. The value of FCV 111 can be either COUNT-1 or COUNT. When IDE 119 is generated to be equal to COUNT-1, FCV 114 can either be equal to IDE 119 or (when the extra cycle bullet is generated) be equal to IDE 119 plus one.

FIG. 4 illustrates a second AND gate 52 and a fifth flip flop 53 that output an extra cycle bullet 113 that causes the fast clock counter 56 to count for an addition cycle—adding one to IDE 119. The extra cycle bullet 113 is a signal that is has duration of a single fast clock cycle and is generated after COUNT-1 is generated—in case that there is a need to add one to IDE 119.

When such an implementation is provided IDE 119 can be reviewed as the signal outputted by the fast clock counter 56 before the extra cycle bullet 113 is generated and FCV 114 is the output signal outputted by the fast clock counter 56 as a result of the generation of the extra cycle bullet 113—that causes the full clock counter 56 to count an additional fast clock cycle. FCV 114 equals IDE 119 if there is no need to count this additional fast clock cycle.

TABLE 2

| Earliest | Last | | | | |
|---|---|---|---|---|---|
| clock | clock | HCV | | | |
| edge | edge | 115 | IDE 119 | FCV 114 | SCED 118 |
| Rising | Rising | −0.5 | COUNT − 1 | COUNT − 1 | COUNT − 0.5 |
| edge | edge | | | | |
| Falling | Falling | +0.5 | COUNT − 1 | COUNT | COUNT + 0.5 |
| edge | edge | | | | |
| Rising | Falling | 0 | COUNT − 1 | COUNT | COUNT |
| edge | edge | | | | |
| Falling | Rising | 0 | COUNT − 1 | COUNT | COUNT |
| edge | edge | | | | |

The half cycle adjustment module 60 is arranged to select to add one half of the fast clock cycle to the duration estimate if the determination result indicates that the earliest fast clock edge and the last fast clock edge are both falling clock edges or raising clock edges.

The half cycle adjustment module 60 is arranged to select to add one half of the fast clock cycle to the duration estimate if the determination result indicates that one of the earliest fast clock edge and the last fast clock edge is a falling clock edge and another clock edge of the earliest fast clock edge and the last fast clock edge is a raising clock edge.

### Fast Clock Edge Type Detector

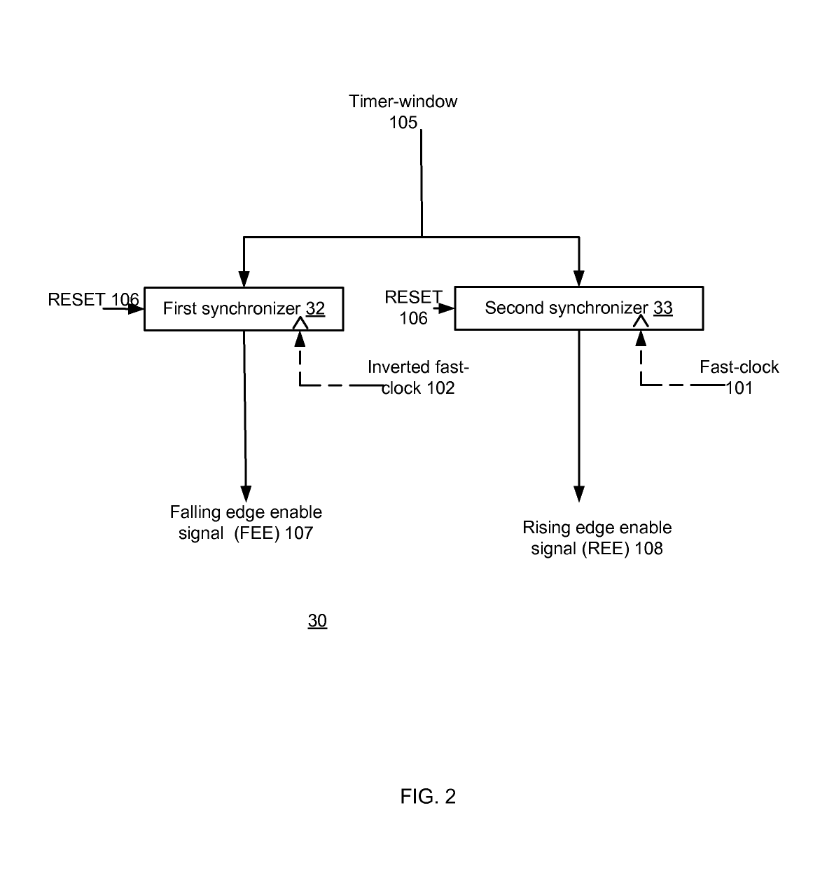

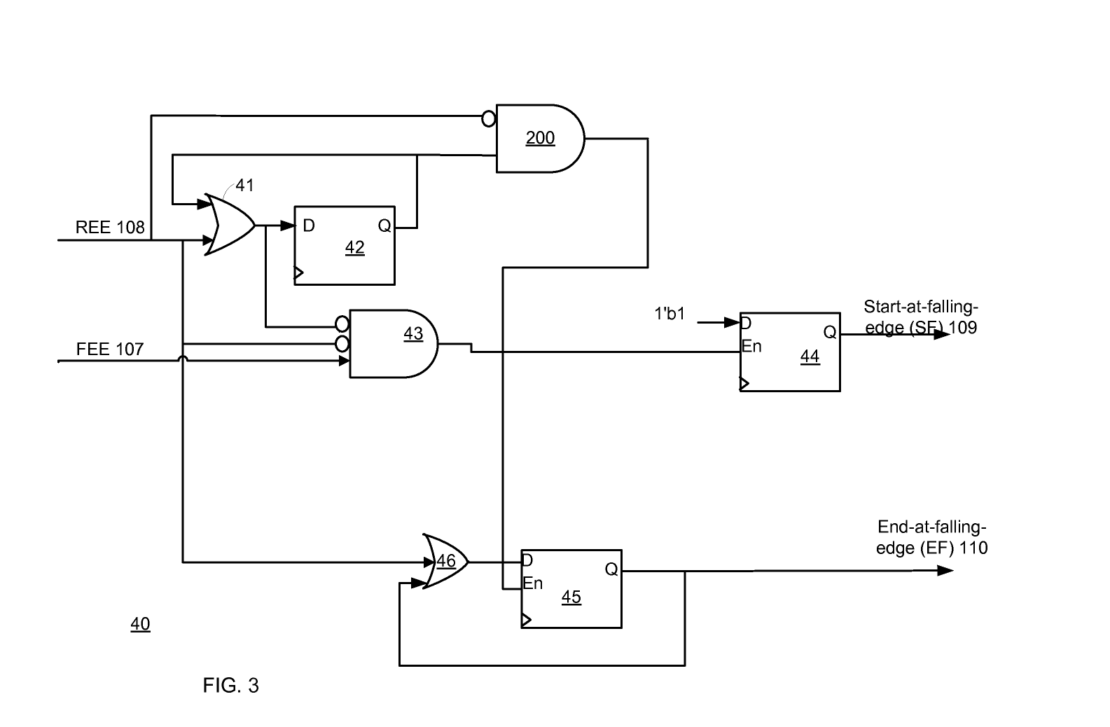

FIGS. 2 and 3 illustrate a fast clock edge type detector 120 according to an embodiment of the invention.

FIG. 2 illustrates a timing signal generator such as a FEE and REE generator 30, while FIG. 3 illustrates a comparator such as case detector 40. The case detector 40 is fed by FEE and REE signals 108 and 107 and determines the type of earliest and last fast clock edges.

The FEE and REE generator 30 is illustrates as including:
1. A fast clock rising edge synchronizer (such as second synchronizer 33) that is arranged to provide a rising edge enable signal (REE) 108 indicative of first period that starts at an occurrence of an earliest rising edge of the fast clock during the slow clock event and ends at a first rising edge of the fast clock after an end of the slow clock event; and
2. A fast clock falling edge synchronizer (such as first synchronizer 32) that is arranged to provide a falling edge enable signal (FEE) 107 indicative of first period that starts at an occurrence of an earliest falling edge of the fast clock during the slow clock event and ends at a first falling edge of the fast clock after an end of the slow clock event. The first synchronizer 32 may be fed by an inverted fast clock 102 or may have an inverted clock input. This inversion causes a falling edge of the fast clock to become a negative edge of the fast clock.

These synchronizers (32, 33) may also receive a RESET signal 106 that resets them.

Type detector 40 is a comparator that is arranged to compare timing of changes in values of the rising edge enable signal with timing of changes in values of the falling edge enable signal to provide the determination result. The timing of changes can be evaluated by processing FEE 107 and REE 108 and especially comparing between the timing of changes in these signals.

For example, assuming that the slow clock event starts by asserting event signal 105 and ends by negating event signal 105 then:
1. If FEE 107 is asserted before REE 108 is asserted than the earliest fast clock edge is a falling edge.
2. If FEE 107 is asserted after REE 108 is asserted than the earliest fast clock edge is a rising edge.
3. If FEE 107 is negated before REE 108 is negated than the last fast clock edge is a falling edge.
4. If FEE 107 is negated after REE 108 is negated than the last fast clock edge is a rising edge.

Yet for another example, assuming that the slow clock event starts by negating event signal 105 and ends by asserting event signal 105 then:
1. If FEE 107 is negated before REE 108 is negated than the earliest fast clock edge is a falling edge.
2. If FEE 107 is negated after REE 108 is negated than the earliest fast clock edge is a rising edge.
3. If FEE 107 is asserted before REE 108 is asserted than the last fast clock edge is a falling edge.
4. If FEE 107 is asserted after REE 108 is asserted than the last fast clock edge is a rising edge.

The case detector 40 can output the determination results in various manners.

FIG. 3 illustrates that the case detector 40 outputs a start by falling edge (SF) signal 109 (indicating that the earliest fast clock edge is a failing edge) and a end at falling edge (EF) signal 110 (indicating that the last fast clock edge is a failing edge). The occurrence of rising edge scenarios can be deducted from the absence of these signals.

FIG. 3 illustrates an example of a case detector 40 that implements this logic. Other arrangements can be also used.

Case detector 40 is illustrated as including a first OR gate 41, a first flip-flop (FF) 42, a first AND gate 43, a second FF 44 that outputs SF 109, a second AND gate 46 and a third FF 45 that outputs EF 110.

All flip-flops in all the figures are D-type flip-flops but other types of flip-flops can be used.

Table 3 illustrates the connectivity of the components of FIG. 3:

TABLE 3

| | | | Third | |
|---|---|---|---|---|
| Unit | First input | Second input | input | output |
| First | Receives REE 108 | Coupled to | | Coupled to input (D) |
| OR | | output (Q) of | | of first FF 42 and to |
| gate 41 | | first flip-flop | | first inverted input of |
| | | 42 and to | | first OR gate 43. |
| | | second input | | |
| | | of fifth AND gate | | |
| | | 200 | | |
| First | D input coupled to | | Clocked | Q input coupled to |
| FF 42 | output of first OR gate | | by fast | first input of first OR |
| | 41 | | clock | gate 41 and to second |
| | | | | input of fifth AND |
| | | | | gate 200 |
| First | First inverted input | Second | Third | Coupled to enable |
| AND | coupled to output of | inverted input | input | input of second FF 44 |
| gate 43 | first OR gate 41 | receives REE | receives | |
| | | 108 | FEE | |
| | | | 107 | |
| Second | D input receives a | Enable input | Clocked | Outputs SF 109 |
| FF 44 | constant “1” (denoted | coupled to the | by fast | |
| | 1′b1) | output of first | clock | |
| | | AND gate 43 | | |
| Second | Receives FEE 107 | Coupled to | | Coupled to D input of |
| OR | | output of third | | third FF 45 |
| gate 46 | | FF 45 | | |
| Third | D input coupled to | Enable input | Clocked | Outputs EF 110 |
| FF 45 | output of second OR | coupled to | by an | |
| | gate 106 | output of fifth | inverted | |
| | | AND gate 200 | fast | |
| | | | clock | |
| Fifth | Receives REE 108 via | Coupled to the | | Coupled to enable |
| AND | inverted input | output of first | | input of third FF 45 |
| gate | | FF 42 | | |
| 200 | | | | |

### Fact Clock Counter Module

FIG. 4 illustrates the full cycle counter 50 according to an embodiment of the invention.

Full cycle counter 50 includes a third OR gate 51, second AND gate 52, fifth FF 53, fourth FF 58, fourth OR gate 55 and fast clock counter 56.

Third OR gate 51 receives SF 109 and EF 110 and is coupled to second OR gate 52 and fifth flip flop. These components output the extra cycle bullet 113 one cycle after the end of the slow clock even in all cases—except when the earliest and last fast clock edges are rising edges (and ST and EF are both zero).

The fast clock counter 56 may be a single type edge counter—it may count only when one type of a clock edge (such as raising edge) is fed to it. Fast clock counter 56 is fed by fast clock (FC) 101. It counts while it receives a positive enable signal at its enable input.

The fourth flip flop 53 that delays the beginning of the counting process by one fast clock cycle to allow the fast clock counter to output COUNT-1 and has additional enable timing control elements that may generate the extra cycle bullet 113 that causes the fast lock counter 56 to count one fast clock cycle after the end of slow clock event—in order to add one fast clock cycle to COUNT-1.

Table 4 illustrates the connectivity of the components of FIG. 4:

TABLE 4

| | | | Third | |
|---|---|---|---|---|
| Unit | First input | Second input | input | output |
| Third | Receives SF 109 | Receives EF | | Coupled to second |
| OR | | 110 | | input of second AND |
| gate 51 | | | | gate 52 |
| Fourth | D input receives REE | | | Q output coupled to |
| FF 59 | 108 | | | third inverting input |
| | | | | of second AND gate |
| | | | | 52 and to second |
| | | | | input of forth OR |
| | | | | gate 55 |
| Second | First input coupled to | Second input | Third | Coupled to enable |
| OR | Q output of fifth FF | coupled to | inverting | input of fifth FF 53 |
| gate 52 | 53 | output of third | input | |
| | | OR gate 51 | coupled | |
| | | | to output | |
| | | | Q of | |
| | | | fourth | |
| | | | FF 54 | |
| Fifth | D input receives a | Enable input | | Outputs extra cycle |
| FF 53 | constant “1” (denoted | coupled to the | | bullet 113 to first |
| | 1′b1) | output of | | input of forth OR |
| | | second AND | | gate 55 |
| | | gate 52 | | |
| Forth | Receives extra cycle | Coupled to | | Coupled to enable |
| OR | bullet 113 | output Q of | | input of fast clock |
| gate 55 | | fourth FF 54 | | counter 56 |
| Fast | Enable input coupled | Clock input | | Outputs FCV 144 and |
| clock | to output of forth OR | receives fast | | IDE 119 |
| counter | gate 55 | clock FC 101 | | |
| 56 | | | | |

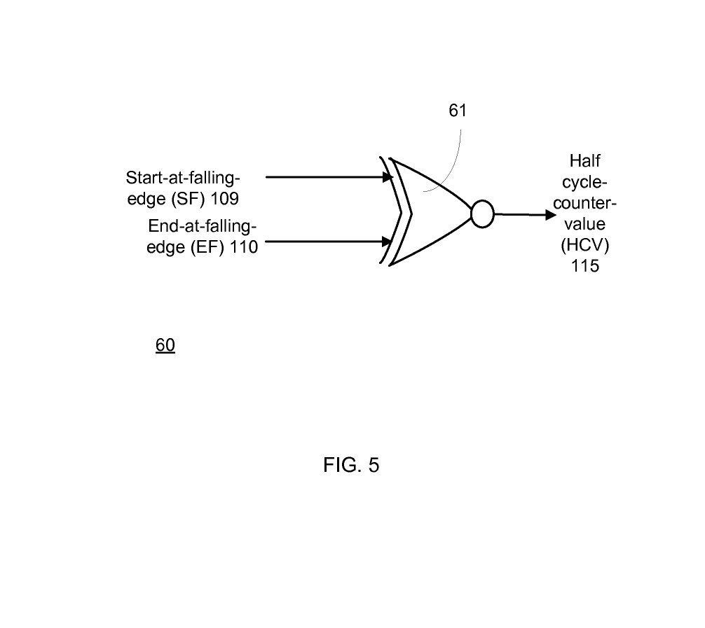

FIG. 5 illustrates the half cycle adjustment module 60 according to an embodiment of the invention. It includes a NXOR gate 61 that receives SF 109 and EF 110 and outputs HCV 115 of a value that indicates that there is a need to add one half of a fast clock cycle if the types (falling edge or rising edge) of the earliest edge and the last edge are the same. In binary representation HCV 115 can be a single digit that appears at the right side of the point while the FCV 114 appears to the left of that point.

### Ignoring Falling Edge Cycle Information

According to various embodiments of the invention there may be a need to provide backward compatibility or otherwise to perform a measurement process that takes into account only information obtained for rising edges of the fast clock.

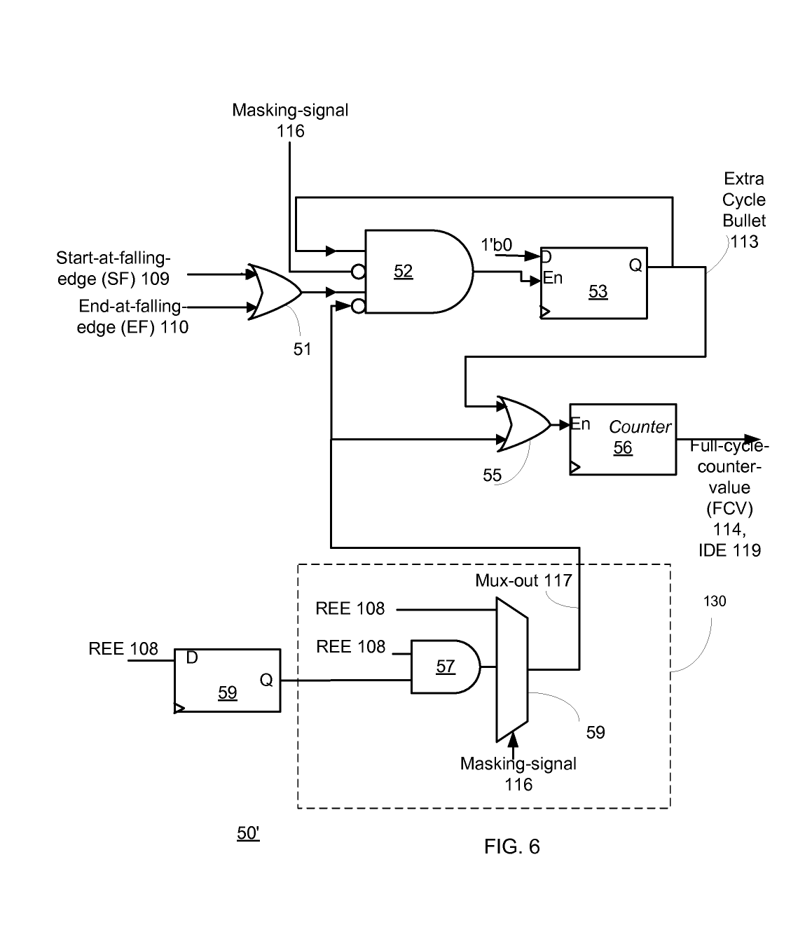

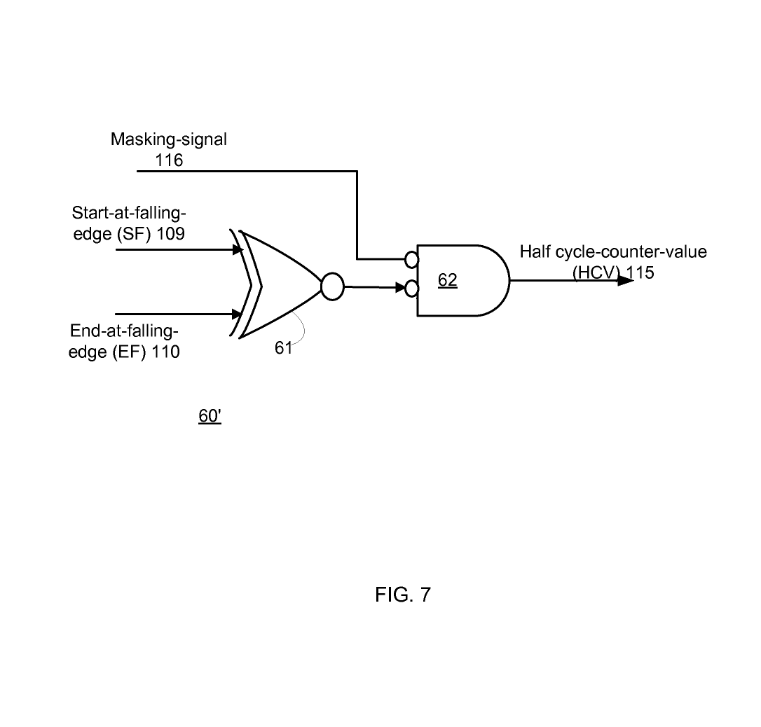

FIG. 6 illustrates a full cycle counter 50′ that prevent the delay of one fast clock cycle of the counting process of he fast clock counter 56 and can be prevented from generating the extra cycle bullet 113 (and thereby provide COUNT as FCV) when receiving a masking signal 116. FIG. 7 illustrates a half cycle adjustment module 60′ that can be masked when receiving the masking signal 116.

Full cycle counter 50′ differs from full cycle counter 50 of FIG. 5 by (a) having a fourth inverting input of the second AND gate 52 that is fed by the masking signal 116, and by (b) having an intermediate circuit 130 between the Q output of the fourth FF 53, the forth OR gate 44 and the third inverting input of the second AND gate 52. This intermediate circuit 130 causes the fast clock counter to do counting process that is responsive to rising edges of the fast clock—perform a counting process that will provide COUNT.

The intermediate circuit 130 includes a third AND gate 57 and a two to one multiplexer 59. The Q output of the fourth FF 53 is coupled to a first input of the third AND gate 57. The second input of the third AND gate 57 is fed by REE 108. The output of the third AND gate 57 is coupled to a first input of multiplexer 59, while the second input of the multiplexer 59 receives REE 108. The multiplexer 59 is controlled by masking signal 116. The output signal (mux-out 117) of the multiplexer 59 is the output signal of the intermediate circuit 130.

Miscellaneous

In order to save power the slow clock can be used for longer periods than the fast clock. The slow clock can be an inaccurate clock and the fast clock can be an accurate clock. The measurement of the slow clock event can be performed from time to time and assist in determining the accuracy and duration of the slow clock for calibration purposes—or for other purposes.

The following examples will illustrate why the mentioned above system provides a better accuracy than pure rising edge based circuits in which the counting process is responsive only to rising edges of the fast clock.

Table 5 provides an example that explains why the half cycle adjustment improves the accuracy of the estimation of the duration of the slow clock event.

Column “length” indicates whether the example is a longest case scenario or a shortest case scenario. The longest case scenario indicates the longest slow clock event that will be still be counted as having a duration of X fast clock cycles while the shortest case scenario indicates the shortest slow clock event that will be still be counted as having a duration of X fast clock cycles.

In the following table R represents a rising edge and F represents a falling edge. The combination of these two letters indicates the case. For example “RR” indicates that the earliest clock cycle and the last clock cycle are rising edges.

COUNT values of 3 or 4 are merely examples.

| | | Real | | | Add full | Half cycle | Output | |
|---|---|---|---|---|---|---|---|---|
| Case | Length | length | COUNT | COUNT − 1 | cycle? | indication | 118 | error |
| RR | Shortest | 3 | 4 | 3 | No | Yes | 3.5 | 0.5 |
| RR | Longest | 4 | 4 | 3 | No | Yes | 3.5 | −0.5 |
| FF | Shortest | 3 | 3 | 2 | Yes | Yes | 3.5 | 0.5 |
| FF | Longest | 4 | 3 | 2 | Yes | Yes | 3.5 | −0.5 |
| RF | Shortest | 3.5 | 4 | 3 | Yes | No | 4 | 0.5 |
| RF | Longest | 3.5 | 4 | 3 | Yes | No | 4 | −0.5 |
| FR | Shortest | 3.5 | 4 | 3 | Yes | No | 4 | 0.5 |
| FR | Longest | 4.5 | 4 | 3 | Yes | No | 4 | −0.5 |

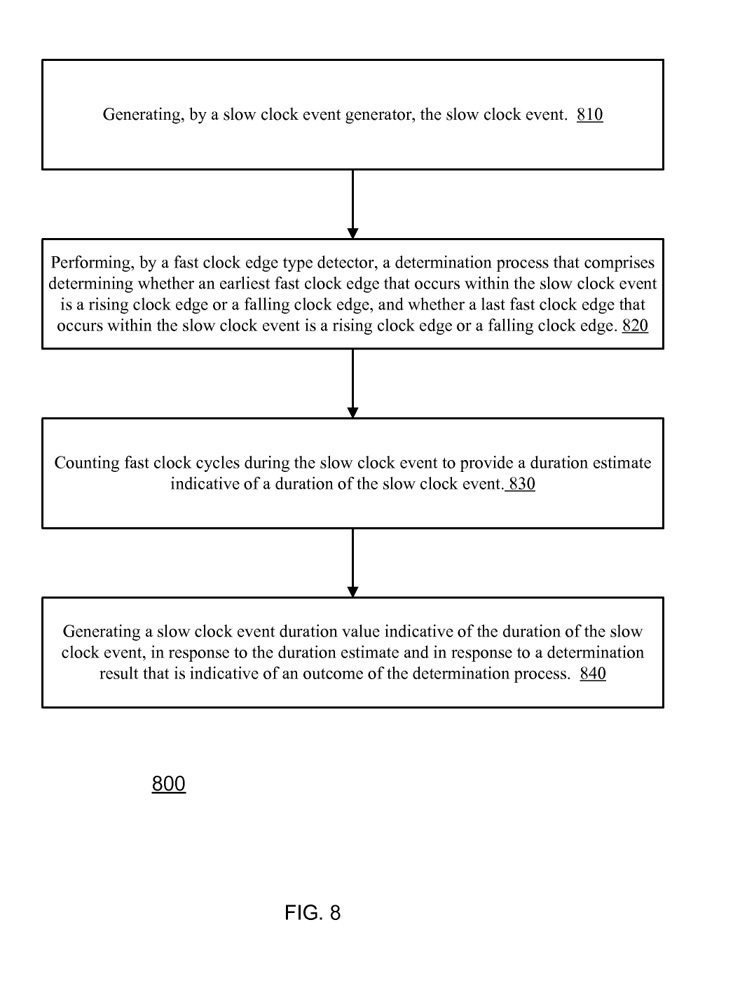

FIG. 8 illustrates method 800 according to an embodiment of the invention. The method includes a sequence of the stages: (A) Stage 810 of Generating, by a slow clock event generator, the slow clock event; (B) Stage 820 of performing, by a fast clock edge type detector, a determination process that comprises determining whether an earliest fast clock edge that occurs within the slow clock event is a rising clock edge or a falling clock edge, and whether a last fast clock edge that occurs within the slow clock event is a rising clock edge or a falling clock edge; (C) Stage 830 of counting fast clock cycles during the slow clock event to provide a duration estimate indicative of a duration of the slow clock event; (D) Stage 840 of generating a slow clock event duration value indicative of the duration of the slow clock event, in response to the duration estimate and in response to a determination result that is indicative of an outcome of the determination process.

It is noted that the previous description related to clock signals having a duty cycle of 50%. If the duty cycle differs then 50% the system should be arranged to distinguish between RF and FR scenarios—and provide a correction signal the reflects this distinction. Thus, instead of adding or subtracting half a clock cycle from the duration estimate (generated by the full clock counter), the half cycle counter (which can be terms fractional clock counter) can indicate whether to add or subtract a first fast clock cycle fraction that corresponds to RF situation or to add or subtract another fast clock cycle fraction the corresponds to FR situation.

The following reference numbers were allocated to the following elements:

| | |
|---|---|
| System | 10 |
| Slow clock event generator | 20 |
| FEE and REE generator | 30 |
| First synchronizer | 32 |
| Second synchronizer | 33 |
| Case detector | 40 |
| First OR gate | 41 |
| First filp flop (FF) | 42 |
| First AND gate | 43 |
| Second FF | 44 |
| Third FF | 45 |
| Second OR gate | 46 |
| Full cycle counter | 50 |
| Third OR gate | 51 |
| Second AND gate | 52 |
| Fifth FF | 53 |
| Fourth OR gate | 55 |
| Third AND gate | 57 |
| Fourth FF | 58 |
| Multiplexer | 59 |
| Half cycle adjustment module | 60 |
| NXOR gate | 61 |
| Fourth AND gate | 62 |
| Counter interface | 70 |
| Slow clock generator | 80 |
| Fast clock generator | 90 |
| Fast clock counter module | 100 |
| Fast clock | 101 |
| Inverted fast clock | 102 |
| Slow clock | 103 |
| Event signal | 104 |
| Reset | 105 |
| Falling edge enable signal (FEE) | 107 |
| Rising edge enable signal (REE) | 108 |
| Start by falling edge (SF) | 109 |
| End by failing edge (ED) | 110 |
| Delayed counter enable | 112 |
| Extra cycle bullet | 113 |
| Full cycle counter value (FCV) | 114 |
| Half cycle counter value (HCV) | 115 |
| Masking signal | 116 |
| Mux-out | 117 |
| Fast clock edge type detector | 120 |
| Intermediate circuit | 130 |
| Fifth AND gate | 200 |

The assignment of the same reference numbers to various components may indicate that these components are similar to each other.

In the foregoing specification, the invention has been described with reference to specific examples of embodiments of the invention. It will, however, be evident that various modifications and changes may be made therein without departing from the broader spirit and scope of the invention as set forth in the appended claims.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

The connections as discussed herein may be any type of connection suitable to transfer signals from or to the respective nodes, units or devices, for example via intermediate devices. Accordingly, unless implied or stated otherwise, the connections may for example be direct connections or indirect connections. The connections may be illustrated or described in reference to being a single connection, multiple connections, unidirectional connections, or bidirectional connections. However, different embodiments may vary the implementation of the connections. For example, separate unidirectional connections may be used rather than bidirectional connections and vice versa. Also, multiple connections may be replaced with a single connection that transfers multiple signals serially or in a time multiplexed manner. Likewise, single connections carrying multiple signals may be separated out into various different connections carrying subsets of these signals. Therefore, many options exist for transferring signals.

Although specific conductivity types or polarity of potentials have been described in the examples, it will be appreciated that conductivity types and polarities of potentials may be reversed.

Each signal described herein may be designed as positive or negative logic. In the case of a negative logic signal, the signal is active low where the logically true state corresponds to a logic level zero. In the case of a positive logic signal, the signal is active high where the logically true state corresponds to a logic level one. Note that any of the signals described herein can be designed as either negative or positive logic signals. Therefore, in alternate embodiments, those signals described as positive logic signals may be implemented as negative logic signals, and those signals described as negative logic signals may be implemented as positive logic signals.

Furthermore, the terms “assert” or “set” and “negate” (or “deassert” or “clear”) are used herein when referring to the rendering of a signal, status bit, or similar apparatus into its logically true or logically false state, respectively. If the logically true state is a logic level one, the logically false state is a logic level zero. And if the logically true state is a logic level zero, the logically false state is a logic level one.

Those skilled in the art will recognize that the boundaries between logic blocks are merely illustrative and that alternative embodiments may merge logic blocks or module elements or impose an alternate decomposition of functionality upon various logic blocks or module elements. Thus, it is to be understood that the architectures depicted herein are merely exemplary, and that in fact many other architectures can be implemented which achieve the same functionality.

Any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

Also for example, in one embodiment, the illustrated examples may be implemented as circuitry located on a single integrated circuit or within a same device. Alternatively, the examples may be implemented as any number of separate integrated circuits or separate devices interconnected with each other in a suitable manner.

Also for example, the examples, or portions thereof, may implemented as soft or code representations of physical circuitry or of logical representations convertible into physical circuitry, such as in a hardware description language of any appropriate type.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

1. A system for measuring a slow clock event, comprising:
a slow clock event generator arranged to generate the slow clock event;
a fast clock edge type detector, coupled to the slow clock event generator, that is arranged to perform a determination process that comprises determining whether an earliest fast clock edge that occurs within the slow clock event is a rising clock edge or a falling clock edge, and whether a last fast clock edge that occurs within the slow clock event is a rising clock edge or a falling clock edge;
a counter module that is arranged to:
count fast clock cycles during the slow clock event to provide a duration estimate indicative of a duration of the slow clock event; and
generate a slow clock event duration value indicative of the duration of the slow clock event, in response to the duration estimate and in response to a determination result that is indicative of an outcome of the determination process.

2. The system according to claim 1, wherein the counter module comprises:
a half cycle adjustment module that is arranged to determine whether to amend the duration estimate by one half of a fast clock cycle; and
a full cycle counter that is arranged to provide the duration estimate.

3. The system according to claim 1, wherein the half cycle adjustment module is arranged to determine whether to (a) add one half of a fast clock cycle to the duration estimate, (b) reduce one half of the fast clock cycle from the duration estimate, or (c) remain the duration estimate unchanged.

4. The system according to claim 3, wherein the half cycle adjustment module is arranged to determine to add one half of the fast clock cycle to the duration estimate if the determination result indicates that the earliest fast clock edge and the last fast clock cycles are falling clock edges.

5. The system according to claim 3, wherein the half cycle adjustment module is arranged to determine to reduce one half of the fast clock cycle from the duration estimate if the determination result indicates that the earliest fast clock edge and the last fast clock cycles are raising clock edges.

6. The system according to claim 3, wherein the half cycle adjustment module is arranged to determine to leave the duration estimate unchanged if the determination result indicates that one of the earliest fast clock edge and the last fast clock edge is a falling clock edge and another clock edge of the earliest fast clock edge and the last fast clock edge is a raising clock edge.

7. The system according to claim 1, wherein the half cycle adjustment module is arranged to select only between an addition of one half of a fast clock cycle to the duration estimate or not to add one half of a fast clock cycle to the duration estimate.

8. The system according to claim 7, wherein the full cycle counter comprises a fast clock counter that is arranged to start counting fast clock cycles one fast clock cycle after an start of the slow clock event, to provide an initial duration estimate.

9. The system according to claim 7, wherein the half cycle adjustment module is arranged to select to add one half of the fast clock cycle to the duration estimate if the determination result indicates that the earliest fast clock edge and the last fast clock edge are both falling clock edges or raising clock edges.

10. The system according to claim 7, wherein the half cycle adjustment module is arranged to select to add one half of the fast clock cycle to the duration estimate if the determination result indicates that one of the earliest fast clock edge and the last fast clock edge is a falling clock edge and another clock edge of the earliest fast clock edge and the last fast clock edge is a raising clock edge.

11. The system according to claim 7, wherein the full cycle counter comprises a fast clock counter that is arranged to start counting fast clock cycles one fast clock cycle after an start of the slow clock event, to provide an initial duration estimate.

12. The system according to claim 11, wherein the full cycle counter is further adapted to generate a duration estimate that equals the initial duration estimate if the determination result indicates that one of the earliest fast clock edge and the last fast clock edge is a falling clock edge and another clock edge of the earliest fast clock edge and the last fast clock edge is a raising clock edge

13. The system according to claim 1, wherein the fast clock edge type detector comprises:
a fast clock rising edge synchronizer arranged to provide a rising edge enable signal indicative of first period that starts at an occurrence of an earliest rising edge of the fast clock during the slow clock event and ends at a first rising edge of the fast clock after an end of the slow clock event; and
a fast clock falling edge synchronizer arranged to provide a falling edge enable signal indicative of first period that starts at an occurrence of an earliest falling edge of the fast clock during the slow clock event and ends at a first falling edge of the fast clock after an end of the slow clock event.

14. The system according to claim 13, wherein the fast clock edge type detector comprises a comparator that is arranged to compare timing of changes in values of the rising edge enable signal with timing of changes in values of the falling edge enable signal to determine to provide the determination result.
